(19) United States
(12) Patent Application Publication
(10) Pub. No.: US 2008/0001599 A1
(43) Pub. Date: Jan. 3, 2008

(54) MAGNETOMETER AND GRADIOMETER OF IN-SERIES SUPERCONDUCTING QUANTUM INTERFERENCE DEVICES (SQUIDs)

(75) Inventors: Chiu-Hsien Wu, Yunlin County (TW); Herng-Er Horng, Taipei (TW); Hong-Chang Yang, Taipei (TW); Shieh-Yueh Yang, Taipei County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignees: Herng-Er Horng, Taipei (TW); Hong-Chang Yang, Taipei (TW); Shieh-Yueh Yang, Taipei County (TW)

(21) Appl. No.: 11/735,444

(22) Filed: Apr. 14, 2007

Related U.S. Application Data
(60) Provisional application No. 60/815,517, filed on Jun. 20, 2006.

(51) Int. Cl. G01R 33/022; G01R 33/035

(52) U.S. Cl. 324/248

(57) ABSTRACT

The invention is about cascading high-transition-temperature superconducting quantum interference devices (SQUIDs) for sensing magnetic fields. These SQUIDs in series are connected with coils for picking up detected magnetic signals. Depending on the patterns of pick-up coils, magnetometers or gradiometers, which sense the magnetic field intensity and magnetic field gradient respectively, are achieved. Examples of magnetometers and gradiometers includes cascading high-T_{c} SQUIDs in series are provided.

### CROSS-REFERENCE TO RELATED APPLICATION

This application claims the priority benefit of U.S. provisional application Ser. No. 60/815,517, filed on Jun. 20, 2006, all disclosures are incorporated therewith.

### BACKGROUND OF THE INVENTION

1. Field of Invention

The present invention relates to sensing structure for sensing magnetic field or magnetic flux. More particularly, the present invention relates to a technology of magnetometer and gradiometer of superconducting quantum interference device (SQUID) to sense magnetic field/flux.

2. Description of Related Art

The conventional superconducting quantum interference device (SQUID) with ultra-high sensitivity to the magnetic flux has been proposed. The SQUID is, for example, popularly applied to sense weak magnetic signals, for example biomagnetic signals. FIG. 1 is a drawing, schematically illustrating a conventional SQUID. A SQUID 100 is usually formed on a substrate. The substrate has a boundary 101. The boundary is, for example, formed two grain region 102a and 102b with a grain boundary. Alternatively for example, the two regions 102a and 102b may have a step height to form a step boundary. The SQUID 100 has the superconducting film as shown in FIG. 1 by shading. The SQUID 100 includes two Josephson junctions 110 in parallel induced by the boundary 101. The electrode lead 104a is disposed on the substrate at the region 102a, usually having two lead terminals. One terminal I 106 is for applying a current through the Josephson junctions 110 and the other terminal V 108 is for detecting an induced voltage signal. The electrode lead 104b is grounded.

The basic detecting mechanism of SQUID is following. When a certain current slightly higher than the critical current of Josephson junctions 110 flows through the Josephson junctions 110, a resistance at the Josephson junction occurs. Then, the resistance induces a voltage level, which can be detected. Due to the property of superconducting material without having magnetic flux, when an external magnetic flux is shone onto a SQUID, a circulating current through these two junctions is induced to compensate the external magnetic field. Thus, a voltage cross the junctions is generated in response to the external magnetic flux.

However, the conventional SQUID can still only detect the intensity of magnetic field having magnetic flux through a small area. To increase the sensing area for achieving a higher sensitivity, SQUIDs are usually hooked with superconducting coils to form magnetometers or gradiometers. On the other hand, with the discovery of high-T_{c} superconductors, SQUID magnetometers or gradiometers made of high-T_{c} superconductors show impact to practical applications because of low system cost and easy cryogenic handling. Thus, various designs of high-T_{c} SQUID magnetometers and gradiometers are still under developing.

### SUMMARY OF THE INVENTION

The invention provides a magnetometer or a gradiometer having a plurality of SQUIDs to more efficiently measuring magnetic flux or intensity gradient of magnetic field. The SQUID can be formed by high-T_{c} superconductors.

The invention provides an embodiment of a SQUID magnetometer, suitable for sensing a magnetic field. The magnetometer includes a plurality of SQUID units. A plurality of superconducting connection parts connects the SQUID units to have a cascade connection. A plurality of electrode leads is respectively connected to the separated SQUID units. Different pair of the electrode leads are taken, the different sensitivity is achieved. This depends on the actual need in use. The present invention can indeed effectively improve the sensitivity of the SQUID magnetometer and can have more application in various choices.

The invention also provides an embodiment of a SQUID magnetometer, including a SQUID set, divided by a boundary into a first part and a second part. The SQUID set has multiple electrode leads respectively at the first part and the second part, and multiple superconducting bars crossing the boundary and connecting the electrode leads in the first part and the second part. A coil-type magnetic-flux sensing part is disposed at the on the same side of the first part with respect to the grain boundary to connect the first part of the SQUID set at the superconducting bars, wherein a material of the coil-type magnetic-flux sensing part is a superconducting material.

The invention also provides a SQUID gradiometer, including at least one SQUID set. Each SQUID set has multiple SQUID units connected side by side and divided by a boundary into a first part and a second part. Multiple electrode leads are connecting to the SQUID units. Different pair of the electrode leads are taken, the different sensitivity is achieved. This depends on the actual need in use. The present invention can indeed effectively improve the sensitivity of the SQUID gradiometer and can have more application in various choices. A first coil-type magnetic-flux sensing part of superconducting material is disposed at the first part. A second coil-type magnetic-flux sensing part of superconducting material, disposed at the second part. A common connection portion is connecting between the SQUID units and connecting to the first coil-type magnetic-flux sensing part and the second coil-type magnetic-flux sensing part. The first coil-type magnetic-flux sensing part senses a first magnetic flux and the second coil-type magnetic-flux sensing part senses a second magnetic flux, to obtain a magnetic field gradient.

It will be apparent to those ordinarily skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a drawing, schematically illustrating a conventional SQUID.

FIG. 2 is drawing, schematically illustrating structure of a bare SQUID, according to an embodiment of the invention.

FIG. 3 is a drawing, schematically illustrating a SQUID magnetometer, according to an embodiment of the invention.

FIG. 4 is a drawing, illustrating a performance of the SQUID magnetometer in FIG. 3, according to an embodiment of the invention.

FIG. 5 is a drawing, illustrating a performance of the SQUID magnetometer in FIG. 3 about the relation of the induced voltage with the magnetic flux, which has been converted into a modulation current, according to embodiment of the invention.

FIG. 6 is a drawing, schematically illustrating the magnetometer of SQUID, according to another embodiment of the invention.

FIG. 7 is a drawing, illustrating a performance of the SQUID magnetometer in FIG. 6 about the variation of induced voltage with the magnetic flux, which has been converted into a modulation current, according to embodiment of the invention.

FIG. 8 is a drawing, illustrating a performance of the SQUID magnetometer in FIG. 6 about the frequency dependence of magnetic field sensitivity.

FIGS. 9-11 are drawings, schematically illustrating another SQUID magnetometer, according to other embodiments of the invention.

FIG. 12 is a drawing, schematically illustrating a SQUID gradiometer, according to other embodiment of the invention.

FIG. 13 is a drawing, schematically illustrating a mechanism of gradiometer.

FIG. 14 is a drawing, illustrating a performance of the SQUID gradiometer in FIG. 12 about the variation of induced voltage with the gradient magnetic flux, which has been converted into a modulation current, according to embodiment of the invention.

FIG. 15 is a drawing, illustrating a performance of the SQUID gradiometer in FIG. 12 about the frequency dependence of magnetic field sensitivity.

FIG. 16 is a drawing, schematically illustrating another SQUID gradiometer, according to another embodiment of the invention.

### DESCRIPTION OF THE PREFERRED EMBODIMENTS

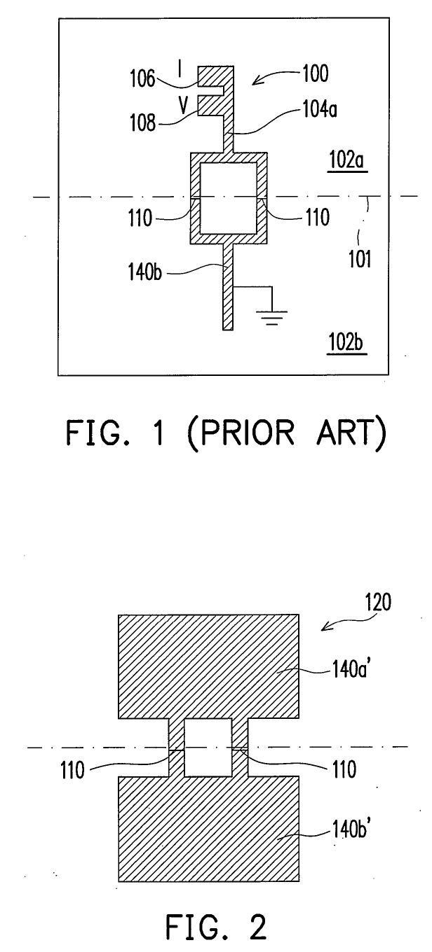

FIG. 2 is drawing, schematically illustrating structure of a bare SQUID, according to an embodiment of the invention. In FIG. 2, a SQUID unit 120 is similar to the SQUID 100 in FIG. 1. However, the electrode leads 104a and 104b in FIG. 1 can be modified into the large electrode leads 104a and 104b. No magnetic flux exits in the electrode leads 104a′ and 104b′, according to the phenomenon of superconducting material. Due to the larger area of the electrode leads 104a′ and 104b′ in superconducting material, the SQUID unit 120 can pick up more magnetic flux, and induce more compensating current in the SQUID unit 120 and then induce the higher voltage signal for detection.

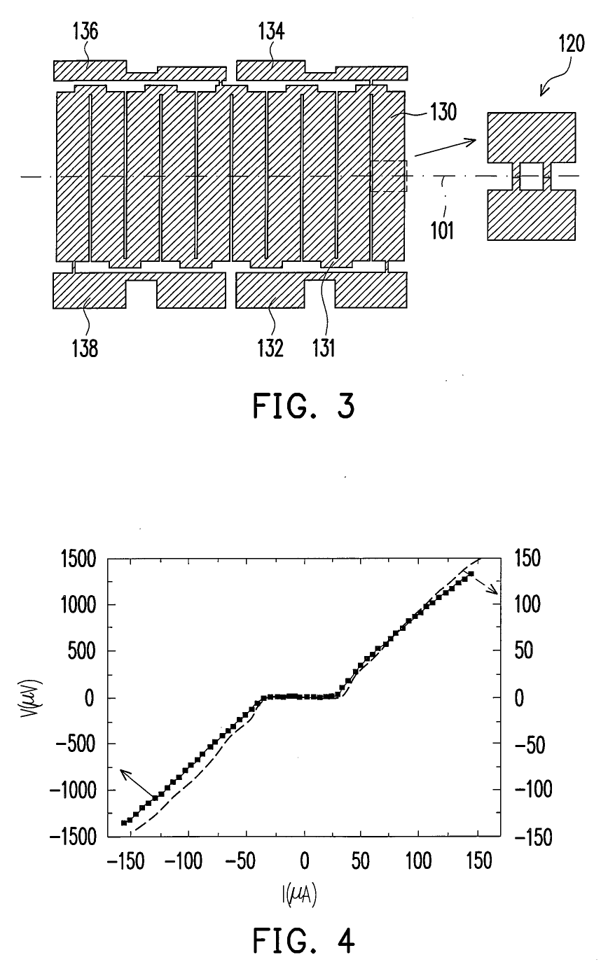

In order to further improve the performance in sensing magnetic flux, which is proportional magnetic field intensity, a magnetometer with multiple SQUID units in cascade connection provided as an embodiment. FIG. 3 is a drawing, schematically illustrating a magnetometer of multiple SQUID units, according to an embodiment of the invention. In FIG. 3, for example, 10 SQUID units are connected together in cascade. The sensing part 130 (also called washer) in superconducting material of the SQUID unit can be the large bars, so as to squeeze more magnetic flux to the central region of the SQUID and induce more compensating current. Several superconducting bridging parts 131 connected the SQUID units as the cascade connection. One bare SQUID unit is shown in larger scale. The bare SQUID unit can be, for example, identical to the one shown in FIG. 2. Then, several electrode leads, such as the electrode leads 132, 134, 136, and 138, are respectively connected to the separated SQUID units, for example. Any pair of the electrode leads can form a sensing set of SQUID units. The connection of the electrode leads to the SQUID units can have several ways. For example, the electrode lead 132 is connected to the first SQUID unit, counting from right to left. The electrode leads 134 and 136 are connected to the intended connecting parts 131. The electrode lead 138 is, for example, connected to the last SQUID unit. Each electrode lead, corresponding to voltage signal and applying current, can have two terminal pads for applying current and detect the induced voltage signal.

In the structure of SQUID as shown in FIG. 3, any pair of the electrode leads can include at least one SQUID unit, connected in cascade. For example, if the electrode leads 132 and 134 are taken, then one SQUID unit is in use. If the electrode leads 132 and 136 are taken, then five SQUID units are in use to sense the magnetic flux. Further example, if the electrode leads 132 and 138 are taken, then ten SQUID units are in use to sense the magnetic flux. The more the SQUID unit is in used, the more the sensitivity is achieved. FIG. 4 is a drawing, illustrating a performance of the SQUID magnetometer in FIG. 3, according to an embodiment of the invention. In FIG. 4, the horizontal axis is the applying current I. The right vertical axis is the induced voltage level for one SQUID unit for dashed line, and the left vertical axis is the induced voltage level for ten SQUID units for dotted line. As one can see, the induced voltage level with ten SQUID units is about ten times of the induced voltage level with one SQUID unit. As one can see, different pair of the electrode leads are taken, the different sensitivity is achieved. This depends on the actual need in use. The present invention can indeed effectively improve the sensitivity of the SQUID magnetometer and can have more application in various choices.

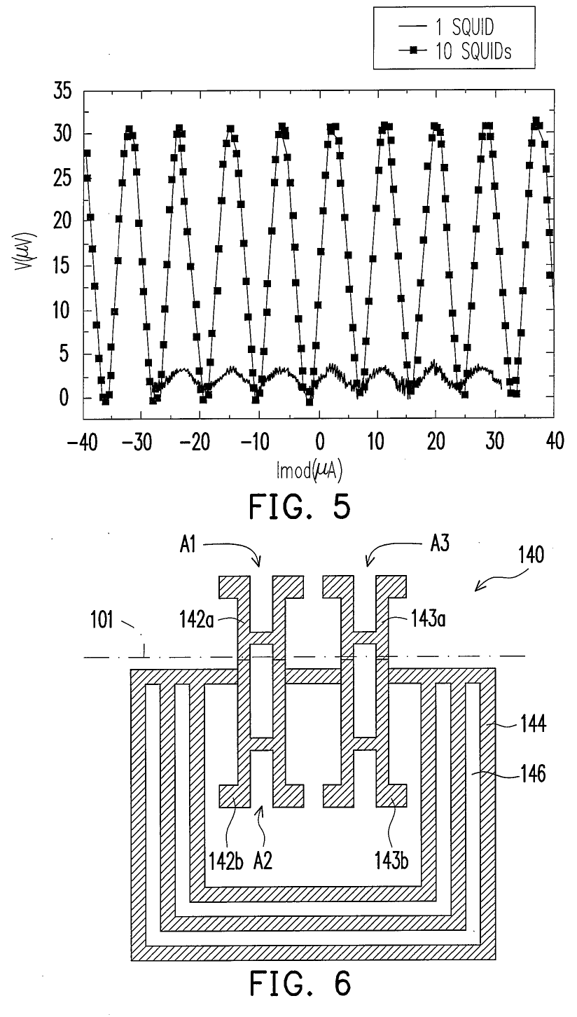

FIG. 5 is a drawing, illustrating a performance of the SQUID magnetometer in FIG. 3 about the relation of the induced voltage with the magnetic flux, which has been converted into a modulation current, according to embodiment of the invention. In FIG. 5, the voltage-flux characteristics are shown in V-I_{mod} curves for a single-SQUID magnetometer and the 10-SQUID array magnetometer at a temperature of 77 K. It is clear that not only the voltage of the single-SQUID magnetometer, but also of the 10-serial-SQUIDs magnetometer vary with the applied magnetic flux. The magnetic flux has been represented by the modulation current I_{mod}. Due to quantum effect, the voltage V varies in period with the magnetic flux. The line curve without symbol is a result from single SQUID unit, in which the induce voltage level is not much. However, the line curve with square symbol is a result from 10 SQUID units connected in cascade, in which the induced voltage level is about ten time larger. In thus situation, the slope is much larger. This indicated that the sensitivity to the magnetic flux is improved. FIG. 5 reveals the fact that the washer-type magnetometer having SQUIDs in series can be used to sense the magnetic flux via measuring the voltage variation.

The sensing part 130 in washer-type may also picking up certain noise. Alternatively, in order to at least reduce the noise level, the washer-type film can be, for example, replaced by a coil-type. FIG. 6 is a drawing, schematically illustrating a performance of the SQUID magnetometer, according to another embodiment of the invention. In FIG. 6, for example, a coil-type SQUID magnetometer 140 can include a SQUID set, which for example includes two SQUID units formed across the boundary 101, dividing each SQUID unit into a first part (upper part) and a second part (lower part). For example, one SQUID unit has electrode leads 142a and 142b, respectively at the first part and the second part. Likewise, the other SQUID unit has the similar electrode leads 143a and 143b. These two SQUID units are cascaded with a superconducting connection between the second parts of the two SQUID units.

Then, a coil-type magnetic-flux sensing part 144 is disposed at, for example, the second part to connect the SQUID units of the SQUID magnetometer. The material of the coil-type magnetic-flux sensing part 144 is also the same superconducting material. If there are many coils included, the coils are separated by a gap 146. The central portion is a free space for adapting the electrode leads of the SQUID units. It should be noted that FIG. 6, just as an example, shows three coils and the three coils 144 are connected to the same line, so as to connect to each of the SQUID unit. However, the number of the coils can be one or several. The coils can also be separately connected to the sides of the SQUID units. The one in FIG. 6 can save the occupied space. With the superconducting properties, each coil increases the sensing capability of magnetic flux. If the electrode pair of A1 and A2 is taken, then one SQUID unit is in use. If the electrode pair of A1 and A3 is taken, then two SQUID units are in use because two sets of Josephson junctions are involved. However, under the basic principle, the cascade connection can be included to use more SQUID units. For example, the connection portion is alternatively changed in two part of the boundary, then the applying current can flow through more number sets of Josephson junctions. It should be noted that the number of SQUID units is not limited to way as shown in FIG. 6, too.

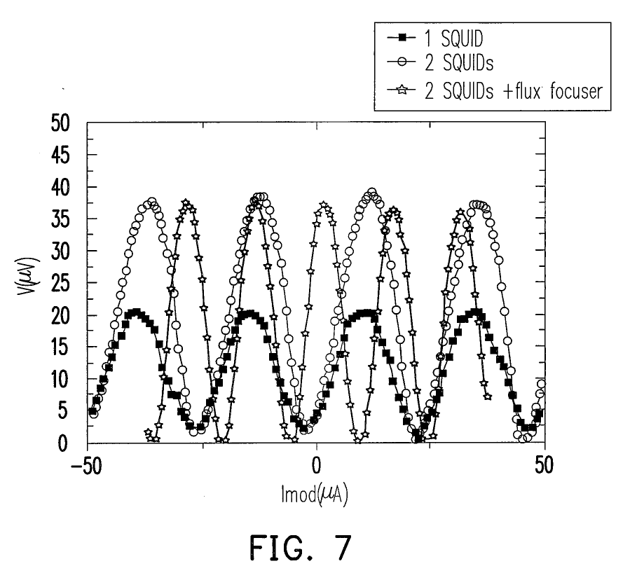

FIG. 7 is a drawing, illustrating a performance of the SQUID magnetometer in FIG. 6 about the variation of induced voltage with the magnetic flux, which has been converted into a modulation current, according to embodiment of the invention. In FIG. 7, the square dotted line is the result from single SQUID unit in use. When two SQUID units are in use, the induced voltage level is shown by open-circle dotted line. Again, the slope of the voltage level is increased. It indicates that the sensitivity is increased by using two SQUID units.

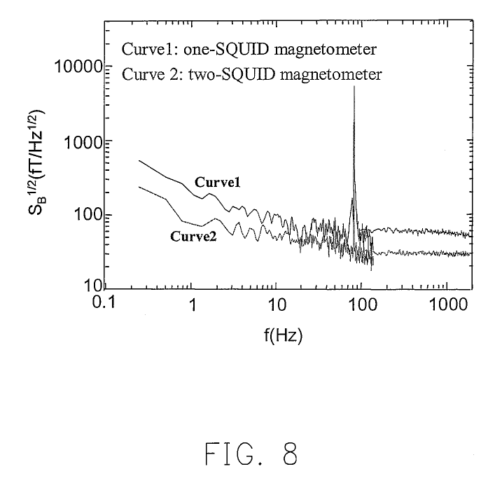

FIG. 8 is a drawing, illustrating a performance of the SQUID magnetometer in FIG. 6 about magnetic field sensitivity S_{B}^{1/2} as a function of the frequency of the sensed magnetic field. In FIG. 8, the curve 1 is the result from the magnetometer with single SQUID unit in use, which shows a filed sensitivity of 42-50 fT/Hz^{1/2} at 1 kHz and 120-150 fT/Hz^{1/2} at 1 Hz. When two SQUID units are in use, the magnetic field sensitivity is shown by the curve 2, which shows a field sensitivity of ˜33 fT/Hz^{1/2} at 1 kHz and ˜80-100 fT/Hz^{1/2} at 1 Hz. The lower value for the magnetic field sensitivity means that the SQUID magnetometer can sense lower magnetic-field intensities. It indicates that the sensitivity is increased by using a magnetometer having more SQUID units.

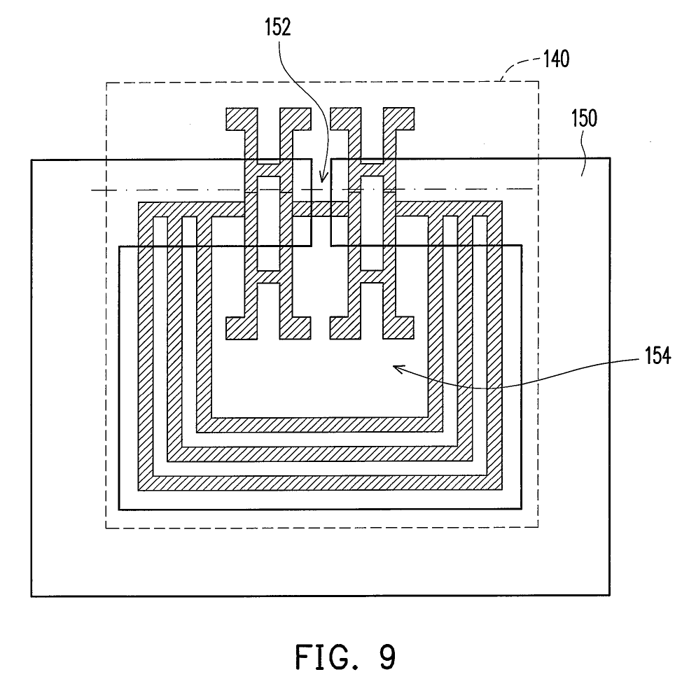

Further, FIG. 9 is a drawing, schematically illustrating another SQUID magnetometer, according to other embodiments of the invention. In FIG. 9, based on the same structure in FIG. 6, a superconducting flux focuser 150 can be further included, disposing over the coil-type magnetometer 140. The superconducting flux focuser 150 is, for example, a C-like shape with an open gap 152 and a free space 154. Since the superconducting flux focuser 150 is also made of superconducting material, in which the magnetic flux cannot exit in side the superconducting material, the superconducting flux focuser 150 can squeeze more magnetic flux into the coil-type magnetometer 140 for sensing. The focusing phenomenon is therefore achieved. With the magnetic focuser 150, the sensibility can be further improved, as shown by star dotted line in FIG. 7. Even though the maximum voltage level for two SQUID units is about the same, the period of flux is reduced with an aid of superconducting flux focuser 150. In this situation, the slope of voltage to the magnetic flux is increased. This phenomenon with focuser also indicates that the sensitivity is improved.

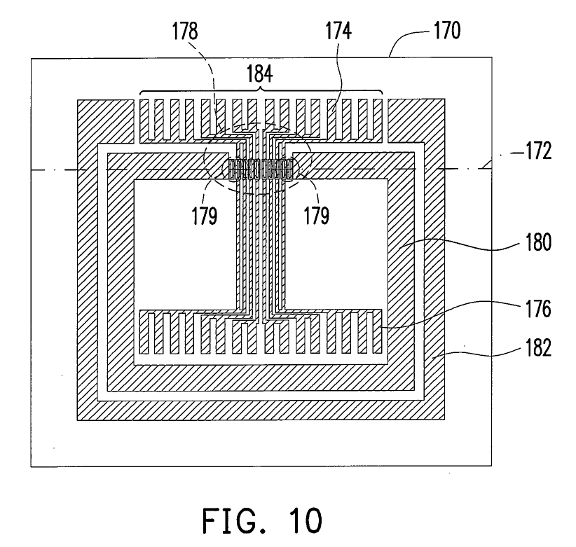

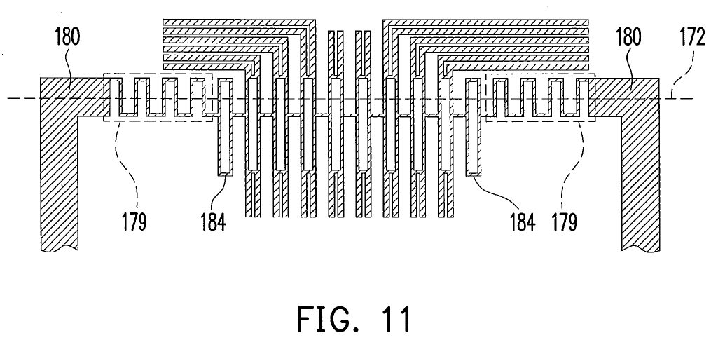

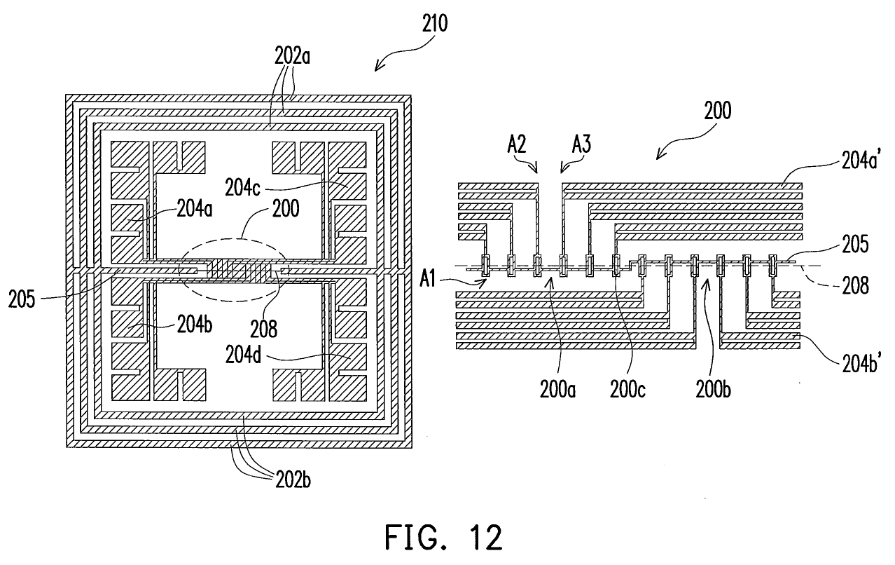

FIG. 10 is a drawing, schematically illustrating another SQUID magnetometer, according to other embodiments of the invention. FIG. 11 shows the magnified structure about the region 178 of FIG. 10. In further consideration, with the same design principle, several SQUID units can be included and connected side by side. The electrode leads 174 and 176 of the SQUID units can be properly arranged without specific choice. However, for example, the location of the electrode leads 176 can be located at the other far opposite side at the periphery of the free space. The number of electrode leads is not limited to a specific quantity. Basically, since there are several electrode leads, when one SQUID is broken, the other SQUID can be used instead. This also true for all of the examples shown in the invention. The magnetic flux focuser 182 may also be included. The coil 180 may be also included. However, in this example of FIGS. 10-11, the gear-like dam structure 179 is presented. The flux dam structure 179 is, for example, connected between the side one of SQUID units and the coil 180, and for example crossing on the boundary 172. According to study of the flux dam, the 1/f noise level at the low frequency can be effectively reduced while the flux dam is included. In addition, the flux dam may also further include a floating SQUID unit 184.

Based on the similar principle, the magnetometer can be further designed into a superconducting gradiometer, which can measure, for example, the gradient of magnetic field intensity. FIG. 12 is a drawing, schematically illustrating a SQUID gradiometer, according to other embodiment of the invention. In FIG. 12, the gradiometer 210 in left drawing can, for example, include two SQUID sets in SQUID region 200 with the coil-type design being put together. The right drawing in FIG. 12 is a magnified structure at the SQUID region 200 having two SQUID sets 200a and 200b.

In general, each of the two SQUID sets 200a, 200b has multiple SQUID units 200c at the SQUID region 200, connected side by side and divided by a boundary 208 into a first part and a second part. Multiple electrode leads 204a, 204b, 204c, and 204d are connecting to the SQUID units. In this example, each SQUID set 200a, 200b has six SQUID units 200c, for example. Each SQUID unit 200c has two electrode leads with, for example, the lead pads for applying current and sensing induced voltage. For a better space distribution, for example, three of the electrode leads go to left direction while the other three electrode leads go to right direction. The lead pads are distributed at the periphery of the free space. It should be noted that the drawing in FIG. 12 is just a schematic drawing. The actual design may be changed under the same principle. One coil set 202a, serving as a coil-type magnetic-flux sensing part, is at one part of the boundary 208 while the other coil set 202b is at the other part of the boundary 208.

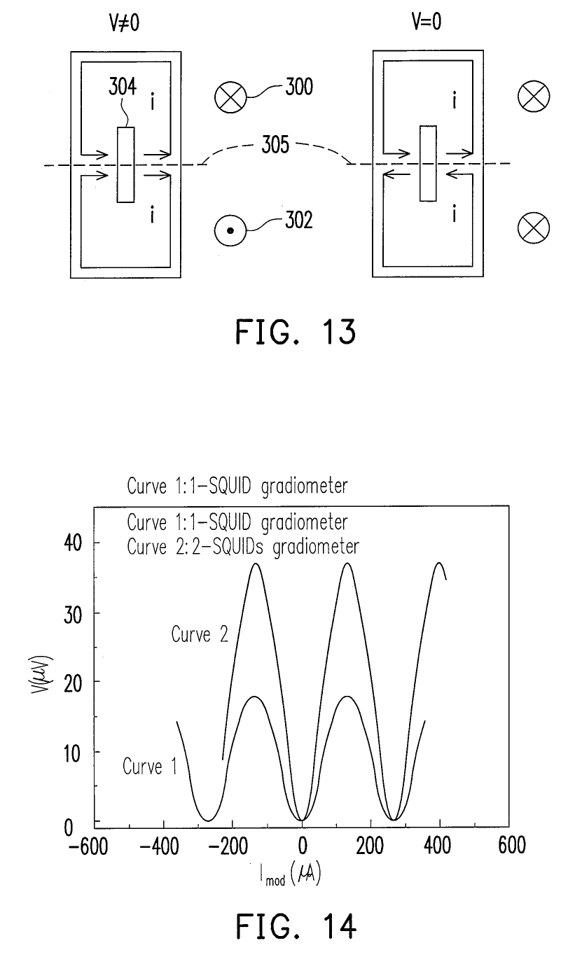

A common connection portion 205 is connected between the SQUID units 200c, and connected to the two coil-type magnetic-flux sensing parts 202a, 202b. Wherein, the coil-type magnetic-flux sensing part 202a senses a magnetic flux and another coil-type magnetic-flux sensing part 202b senses another magnetic flux, so as to obtain a magnetic field gradient. This measuring mechanism is shown in FIG. 13. FIG. 13 is a drawing, schematically illustrating a mechanism of gradiometer. For one SQUID unit 304 across the grain boundary 305, the two coils located at different positions 300 and 302 and enclosed the two side of the SQUID unit. With a common connection. For example, when the magnetic flux at the position 300 is entering the drawing paper while the magnetic flux at the position 302 is going out the drawing paper. Due to the different direction of magnetic flux, the induced current, flowing into the SQUID unit 304, is enhanced. As a result, a non-zero voltage V can be detected. The quantity of V is related to the gradient degree. For the situation with uniform magnetic flux, them the magnetic flux at the position 300 is substantially equal to that at the position 302. The induced currents cancel to each other, causing a zero induced current to the SQUID unit. Then, the voltage is not induced, either, that is V=0. According to this mechanism, the intensity gradient of magnetic field can be measured. For example, if the electrode leads A1 and A2 in FIG. 12 are taken, one SQUID unit is in use. If the electrode leads A2 and A3 are taken, then two SQUID units are in use with better sensitivity. As mentioned above in FIG. 6, the choice and the design of the electrode leads can be changed, according to the actual design. More SQUID units can be included in use.

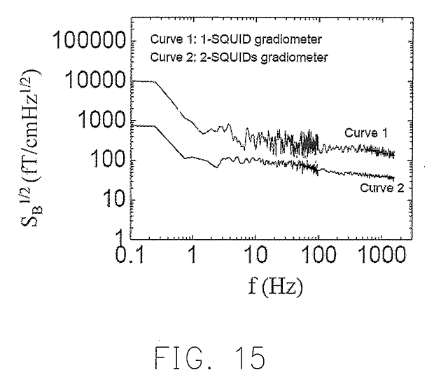

FIG. 14 is a drawing, illustrating a performance of the SQUID gradiometer in FIG. 12 about the variation of induced voltage with the gradient magnetic flux, which has been converted into a modulation current, according to embodiment of the invention. In FIG. 14, the voltage-gradient-flux characteristics are shown in V-I_{mod} curves for 1-SQUID gradiometer and 2-SQUIDs gradiometer at 77 K. It is clear that not only the voltage of the 1-SQUID gradiometer, but also of the 2-serial-SQUIDs gradiometer vary with the gradient magnetic flux. The gradient magnetic flux has been represented by the modulation current I_{mod}. Due to quantum effect, the voltage V varies in period with the magnetic flux. The curve 1 is a result from the gradiometer with single SQUID unit, in which the induce voltage level is about 17 μV. However, the curve 2 is a result from 2 SQUID units connected in cascade for the gradiometer, in which the induced voltage level is about twice larger. In thus situation, the slope is much larger. This indicated that the sensitivity to the gradient magnetic flux is improved. FIG. 14 reveals the fact that the gradiometer having SQUIDs in series can be used to sense the gradient magnetic flux via measuring the voltage variation.

FIG. 15 is a drawing, illustrating a performance of the SQUID grasiometer in FIG. 12 about sensitivity S_{B}^{1/2} in the gradient magnetic field as a function of the frequency of the sensed gradient magnetic field. In FIG. 15, the curve 1 is the result from the gradiometer with single SQUID unit in use, which shows a gradient filed sensitivity of 90˜150 fT/cmHz^{1/2} at 1 kHz and of 1-2 pT/cmHz^{1/2} at 1 Hz. When two SQUID units are in use, the gradient magnetic field sensitivity is shown by the curve 2, which shows a field sensitivity of 50 fT/cmHz^{1/2} at 1 kHz and 100 fT/cmHz^{1/2} at 1 Hz. The lower value for the gradient magnetic field sensitivity means that the SQUID gradiometer can sense lower gradient magnetic-field intensities. It indicates that the sensitivity is increased by using a gradiometer having more SQUID units.

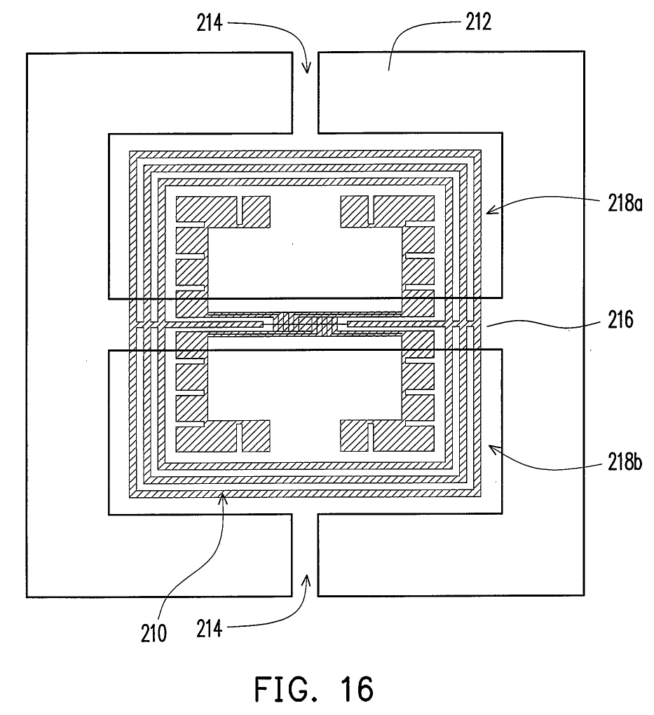

It should also be noted that the foregoing embodiments can be partially or fully combined, according to the actual design. The magnetometer and the gradiometer are based on the same design principle of the present invention. For example, the flux focuser can be furthered used in gradiometer. FIG. 16 is a drawing, schematically illustrating another SQUID gradiometer, according to another embodiment of the invention. In FIG. 16, the flux focuser 212 is over the gradiometer 210, so as to pick up more magnetic flux. However, since the gradiometer includes two sensing locations, the flux focuser 212 is formed in accordance with the structure of the gradiometer 210. For example, the flux focuser 212 is a superconducting film has two E-like structures against to each other with the gaps 214. However, the middle horizontal lines 216 are connected together. As a result, the free space 218a and 218b expose the sensing coils of the gradiometer 210. The size of the flux focuser 212 can be sufficient large to pick up more magnetic flux and squeeze the magnetic flux into the sensing coils.

The present invention has proposed the magnetometer and the gradiometer based on multiple SQUID units being in cascade connections. As a result, the present invention can indeed effectively improve the sensitivity of the magnetometer and the gradiometer, and can have more application in various choices by taking different pair of the electrode leads of SQUID units. This depends on the actual need in use. Further for example, the coil-type and the washer-type for the SQUID can be chosen in option. The flux focuser can be optionally included, too, for increasing the sensitivity with larger sensing area.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is:

1. A magnetometer of superconducting quantum interference device (SQUID), suitable for sensing a magnetic field, comprising:
a plurality of SQUID units;
a plurality of superconducting bridging parts, connecting the SQUID units to have a cascade connection; and
a plurality of electrode leads, respectively connected to the separated SQUID units.

2. The SQUID magnetometer of claim 1, wherein the electrode leads comprise at least two sets of electrode leads, respectively connected to any different SQUID units in the cascade connection.

3. The SQUID magnetometer of claim 1, wherein a pair of the electrode leads corresponds to a specific numbers of the SQUID units being connected in cascade for sensing magnetic flux.

4. The SQUID magnetometer of claim 1, wherein the magnetic field sensitivity is improved by using more numbers of the SQUID units.

5. A magnetometer of superconducting quantum interference device (SQUID), suitable for sensing a magnetic flux, comprising:
a SQUID set, divided by a boundary into a first part and a second part, wherein the SQUID set has multiple electrode leads respectively at the first part and the second part; and
a coil-type magnetic-flux sensing part, disposed at the on the same side of the first part with respect to the grain boundary to connect the first part of the SQUID set at the superconducting bars, wherein a material of the coil-type magnetic-flux sensing part is a superconducting material.

6. The SQUID magnetometer of claim 5, wherein the coil-type magnetic-flux sensing part comprises one superconducting film coil.

7. The SQUID magnetometer of claim 5, wherein the coil-type magnetic-flux sensing part comprises multiple superconducting film coils, distributed from an inner coil to an outer coil.

8. The SQUID magnetometer of claim 5, wherein the SQUID set comprises one SQUID unit or multiple SQUID units connected in series.

9. The SQUID magnetometer of claim 5, further comprise a superconducting flux focuser disposed over the SQUID set and the coil-type magnetic-flux sensing part, to increase a magnetic flux to the coil-type magnetic-flux sensing part.

10. The SQUID magnetometer of claim 5, wherein a pair of the electrode leads corresponds to a specific numbers of SQUID units of the SQUID set being connected in cascade for sensing magnetic flux.

11. The SQUID magnetometer of claim 5, wherein the magnetic field sensitivity is improved by using more numbers of the SQUID units.

12. The SQUID magnetometer of claim 5, further comprising a superconducting dam magnetometer between the coil-type magnetic-flux sensing part and the SQUID set.

13. A gradiometer of superconducting quantum interference device (SQUID), comprising:
at least one SQUID set having multiple SQUID units connected in series and divided by a boundary into a first part and a second part; and multiple electrode leads connecting to the SQUID units;
a first coil-type magnetic-flux sensing part of superconducting material, disposed at the first part; and
a second coil-type magnetic-flux sensing part of superconducting material, disposed at the second part; and
a common connection portion, connecting between the SQUID units and connecting to the first coil-type magnetic-flux sensing part and the second coil-type magnetic-flux sensing part,
wherein the first coil-type magnetic-flux sensing part senses a first magnetic flux and the second coil-type magnetic-flux sensing part senses a second magnetic flux, to obtain a magnetic gradient.

14. The SQUID gradiometer of claim 13, further comprising a superconducting flux focuser disposed over the SQUID set, the first coil-type magnetic-flux sensing part, and the second coil-type magnetic-flux sensing part, to increase a magnetic flux to the first and the second coil-type magnetic-flux sensing parts.

15. The SQUID gradiometer of claim 13, wherein a pair of the electrode leads corresponds to a specific numbers of the SQUID units being connected in use for sensing magnetic flux.

16. The SQUID gradiometer of claim 13, wherein the magnetic-field gradient sensitivity is improved by using more numbers of the SQUID units.
